(19) United States
(12) Patent Application Publication
(10) Pub. No.: US 2026/0268976 A1
(43) Pub. Date: Sep. 10, 2026

(54) MEMORY DEVICE AND OPERATING METHOD THEREOF

(71) Applicant: SK hynix Inc., Icheon-si Gyeonggi-do (KR)

(72) Inventors: Seung Jun LEE, Icheon-si Gyeonggi-do (KR); Jae Hyeon SHIN, Icheon-si Gyeonggi-do (KR)

(73) Assignee: SK hynix Inc., Icheon-si Gyeonggi-do (KR)

(21) Appl. No.: 19/421,999

(22) Filed: Dec. 16, 2025

(30) Foreign Application Priority Data
Mar. 6, 2025 (KR) 10-2025-0028986

(51) Int. Cl. G11C 16/08; G11C 16/26

(52) U.S. Cl. CPC G11C 16/08; G11C 16/26

(57) ABSTRACT

A memory device includes a plurality of memory cells coupled to each of a plurality of word lines, a peripheral circuit configured to perform a first sensing operation on first memory cells, among the plurality of memory cells, coupled to a selected word line among the plurality of memory cells by applying different voltages to the selected word line and unselected word lines, and control logic configured to control the peripheral circuit to perform an operation including applying voltages to the plurality of word lines, in which the control logic determines, based on a magnitude of a first sensing voltage applied to the selected word line during the first sensing operation, a first equalizing time period during which an equalizing voltage is applied to the plurality of word lines after the first sensing operation.

### CROSS REFERENCE TO RELATED APPLICATION

The present application claims priority under 35 U.S.C. §119(a) to Korean patent application number 10-2025-0028986 filed on Mar. 6, 2025, in the Korean Intellectual Property Office, the entire contents of which application is incorporated herein by reference.

### BACKGROUND

### Technical Field

The present disclosure relates to an electronic device, and more particularly, to a memory device and an operating method thereof.

### Related Art

A storage device stores data under the control of a host device, such as a computer, a smartphone, a smartpad, or the like. Depending on the type of device that stores data, a storage device includes a device storing data on a magnetic disk, such as a hard disk drive (HDD), and a device storing data on a semiconductor memory, including a non-volatile memory, such as a solid state drive (SSD) or a memory card.

A storage device may include a memory device in which data is stored and a memory controller that stores data in the memory device. The memory device may be classified into volatile memory and non-volatile memory. Examples of the non-volatile memory include Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), Ferroelectric RAM (FRAM), and the like.

### SUMMARY

According to an embodiment, a memory device may include a plurality of memory cells coupled to each of a plurality of word lines, a peripheral circuit configured to perform a first sensing operation on first memory cells, among the plurality of memory cells, coupled to a selected word line by applying different voltages to the selected word line and unselected word lines among the plurality of word lines, and control logic configured to control the peripheral circuit to perform an operation including applying voltages to the plurality of word lines, wherein the control logic determines, based on a magnitude of a first sensing voltage applied to the selected word line during the first sensing operation, a first equalizing time period during which an equalizing voltage is applied to the plurality of word lines after the first sensing operation.

According to an embodiment, a method of operating a memory device may include applying a pass voltage to an unselected word line of a plurality of word lines, applying a first sensing voltage to a selected word line of the plurality of word lines, and applying an equalizing voltage to the plurality of word lines during a first equalizing time period determined based on the first sensing voltage.

According to an embodiment, a method of operating a memory device may include applying a pass voltage to unselected word lines of a plurality of word lines, applying a first sensing voltage to a selected word line of the plurality of word lines, and performing a first equalizing process by applying an equalizing voltage to the plurality of word lines until a voltage value of the selected word line reaches a reference voltage value.

### BRIEF DESCRIPTION OF THE DRAWINGS

FIG. 1 is a diagram illustrating a storage device according to an embodiment of the present disclosure;

FIG. 2 is a diagram illustrating the structure of a memory device according to an embodiment of the present disclosure;

FIG. 3 is a diagram illustrating an embodiment of a memory cell array according to an embodiment of the present disclosure;

FIG. 4 is a diagram illustrating an embodiment of a memory block according to an embodiment of the present disclosure;

FIG. 5 is a diagram illustrating an embodiment of a memory block according to an embodiment of the present disclosure;

FIG. 6 is a diagram illustrating channel negative boosting occurring in accordance with an embodiment of the present disclosure;

FIG. 7 is a diagram illustrating a shift in threshold voltage distribution due to channel negative boosting according to an embodiment of the present disclosure;

FIG. 8 is a diagram illustrating a threshold voltage distribution of memory cells and corresponding data bits according to an embodiment of the present disclosure;

FIG. 9 is a timing diagram illustrating voltages applied to unselected word lines and a selected word line during a sensing operation and an equalizing operation for an LSB page according to an embodiment of the present disclosure;

FIG. 10 is a timing diagram illustrating voltages applied to unselected word lines and a selected word line during a sensing operation and an equalizing operation for a CSB page according to an embodiment of the present disclosure;

FIG. 11 is a timing diagram illustrating voltages applied to unselected word lines and a selected word line during a sensing operation and an equalizing operation for an MSB page according to an embodiment of the present disclosure;

FIG. 12 is a timing diagram illustrating voltage changes on unselected word lines and a selected word line during a sensing operation and an equalizing operation according to an embodiment of the present disclosure;

FIG. 13 is a timing diagram illustrating voltage changes on a selected word line during an equalizing operation for each of a plurality of pages according to an embodiment of the present disclosure;

FIG. 14 is a timing diagram illustrating voltage changes on a selected word line during an equalizing operation for each of a plurality of pages according to an embodiment of the present disclosure;

FIG. 15 is a flowchart of a method of performing an equalizing operation of a memory device according to an embodiment of the present disclosure;

FIG. 16 is a block diagram illustrating a memory card system to which a storage device is applied according to an embodiment of the present disclosure;

FIG. 17 is a block diagram illustrating a solid state drive (SSD) system including a storage device according to an embodiment of the present disclosure.

FIG. 18 is a block diagram illustrating a user system including a storage device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “coupled” to another element, the elements may be coupled directly or through at least one intervening element between the elements. When two elements are identified as “directly coupled,” one element is directly coupled to the other element without an intervening element between the two elements.

As used herein, the terms “device” or “unit” include a combination of software, firmware, and/or hardware configured to provide the functions described in the present disclosure. For example, software may be implemented with a software package, codes, and/or a set of instructions or a command, and hardware may include a combination or assembly of hardwired circuits, programmable circuits, state machine circuits, processors, and/or firmware that store instructions executable by programmable circuits.

The present disclosure provides a memory device and an operating method that controls a voltage applied to each line to prevent channel negative boosting during a read operation or a verify operation.

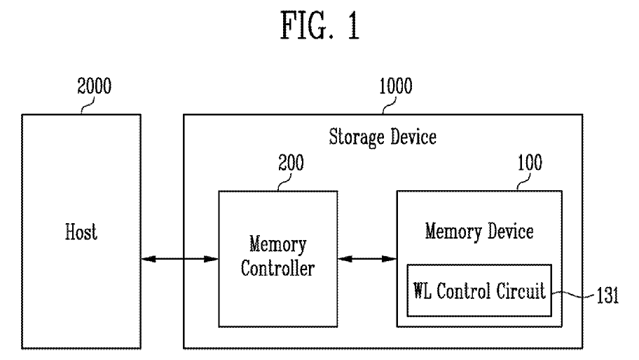

FIG. 1 is a diagram illustrating a storage device 1000 according to an embodiment of the present disclosure.

Referring to FIG. 1, the storage device 1000 may include a memory device 100 and a memory controller 200.

The storage device 1000 may store data. For example, the storage device 1000 may store data under control of a host device 2000, such as a cell phone, a smartphone, an MP3 player, a laptop computer, a desktop computer, a gaming machine, a television, a tablet PC, in-vehicle infotainment system, or the like.

The storage device 1000 may be manufactured as one of a variety of different types of storage devices, for example, depending on a host interface used to communicate with the host 2000. For example, the storage device 1000 may be one of various types of storage devices such as a multimedia card in the form of SSD, MMC, eMMC, RS-MMC, or micro-MMC, a secure digital card in the form of SD, mini-SD, or micro-SD, a universal serial bus (USB) storage device, a universal flash storage (UFS) device, a personal computer memory card international association (PCMCIA) card, a storage device in the form of a peripheral component interconnection (PCI) card, a storage device in the form of a PCI express (PCI-E) card, a compact flash (CF) card, a smart media card, and a memory stick.

The storage device 1000 may be manufactured in one of various package types or forms. For example, the storage device 1000 may be manufactured in one of package on package (POP), system in package (SIP), system on chip (SOC), multi-chip package (MCP), chip on board (COB), wafer-level fabricated package (WFP), and wafer-level stack package (WSP).

The memory device 100 may store data. For example, the memory device 100 may operate in response to control signals from the memory controller 200. The memory device 100 may include a memory cell array including a plurality of memory cells that store data. The memory cell array may include a plurality of memory blocks. Each memory block may include a plurality of memory cells, and the plurality of memory cells may be grouped in a plurality of pages. According to an embodiment, data may be stored in the memory device 100 or read from in the memory device 100 by a unit of a page. Data may be erased by a unit of memory block.

According to an embodiment, the memory device 100 may include Double Data Rate Synchronous Dynamic Random Access Memory (DDR SDRAM), Low Power Double Data Rate4 (LPDDR4) SDRAM, Graphics Double Data Rate (GDDR) SDRAM, Low Power DDR (LPDDR), Rambus Dynamic Random Access Memory (RDRAM), NAND flash memory, Vertical NAND flash memory, NOR flash memory, resistive random access memory (RRAM), phase-change memory (PRAM), magnetoresistive random access memory (MRAM), ferroelectric random access memory (FRAM), spin transfer torque random access memory (STT-RAM), and the like. The memory device 100 is described as a NAND flash memory in the present disclosure for simplicity of description.

According to an embodiment, the memory device 100 may store data bits in each of the plurality of memory cells. For example, the memory device 100 may operate in a manner corresponding to at least one of the following cell types: a single-level cell (SLC) that stores one data bit per memory cell, a multi-level cell (MLC) that stores two data bits per memory cell, a triple-level cell (TLC) that stores three data bits per memory cell, and a quadruple-level cell (QLC) that stores four data bits per memory cell.

The memory device 100 may receive a command and an address from the memory controller 200 and access a region, selected by the address, in the memory cell array. Thus, the memory device 100 may perform an operation corresponding to the command on the region selected by the address. For example, the memory device 100 may perform a write operation (hereinafter also referred to as a program operation), a read operation, or an erase operation based on the received command. For example, when a program command (hereinafter also referred to as write command) is received, the memory device 100 may program data into the region selected by the address. When the memory device 100 receives a read command, the memory device 100 may read data from the region selected by the address. When the memory device 100 receives an erase command, the memory device 100 may erase data stored in the region selected by the address.

According to an embodiment, each of the plurality of memory cells may be coupled to a plurality of word lines. For example, the plurality of word lines may include a selected word line and unselected word lines, and the memory device 100 may perform a sensing operation on memory cells coupled to the selected word line.

According to an embodiment, the memory device 100 may include a word line control circuit 131. During a sensing operation of the memory device 100, the word line control circuit 131 may control voltages applied to the selected word line and the unselected word lines. For example, the word line control circuit 131 may control operations of the memory device 100 to apply the voltages to the selected word line and the unselected word lines.

For example, during a sensing operation, the memory device 100 may apply a sensing voltage to the selected word line and a pass voltage to the unselected word lines. For example, the memory device 100 may perform an equalizing operation after the sensing operation. The memory device 100 may apply equal voltages to the selected word line and the unselected word lines during the equalizing operation. The memory device 100 may discharge the selected word line and the unselected word lines after the equalizing operation. For example, the equalizing operation may prevent channel negative boosting that occurs when a channel voltage changes to a negative value.

As the equalizing operation is performed, a voltage value of the selected word line may be relatively close to the voltage values of the unselected word lines. For example, during the equalizing operation, the memory device 100 may increase a voltage of the selected word line and decrease voltages of the unselected word lines such that the voltage value of the selected word line may be relatively close to the voltage values of the unselected word lines.

According to an embodiment, a read operation or a verify operation performed by the memory device 100 may include a sensing operation and an equalize operation. For example, the sensing operation may be performed to identify threshold voltage levels of the plurality of memory cells. For example, the read operation may be performed to detect data bits stored in the plurality of memory cells. For example, the verify operation may be performed to verify whether the plurality of memory cells are programmed to a desired state during a program operation performed by the memory device 100.

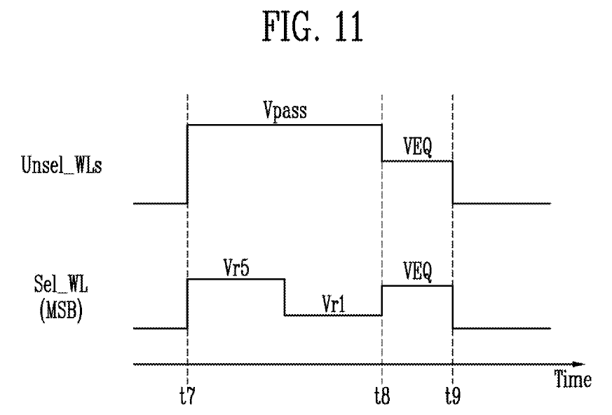

According to an embodiment, the word line control circuit 131 may determine, based on the magnitude of the sensing voltage applied to the selected word line during the sensing operation, an equalizing time period during which an equalizing voltage is applied to the plurality of word lines during the equalizing operation. For example, based on the magnitude of the sensing voltage, the word line control circuit 131 may determine different equalizing time periods. By determining the equalizing time period based on the magnitude of the sensing voltage, the time taken to perform a read operation or a verify operation of the memory device 100 may be reduced. A method by which the word line control circuit 131 determines the equalizing time period is described with reference to FIGS. 11 to 13.

The memory controller 200 may control the overall operation of the storage device 1000.

The memory controller 200 may perform a program operation, a read operation, or an erase operation in response to a request from the host 2000. For example, the memory controller 200 may control the memory device 100 in response to a request from the host 2000. For example, when the memory controller 200 receives a program request from the host 2000, the memory controller 200 may change the program request to a program command and provide the program command, a physical block address PBA, and data to the memory device 100. When a read request and a logical block address LBA are received from the host 2000, the memory controller 200 may change the read request to a read command, select a physical block address corresponding to the logical block address, and provide the read command and the physical block address PBA to the memory device 100. When an erase request and a logical block address are received from the host 2000, the memory controller 200 may change the erase request to an erase command, select a physical block address corresponding to the logical block address, and provide the erase command and the physical block address PBA to the memory device 100.

According to an embodiment, the memory controller 200 may generate and transfer a program command, an address, and data to the memory device 100 without a request from the host 2000. For example, the memory controller 200 may provide a command, an address, and data to the memory device 100 to perform background operations, such as a program operation to perform wear leveling and a program operation to perform garbage collection.

The host 2000 may include one or more processor cores. For example, the host 2000 may be implemented in one or more Field Programmable Gate Arrays (FPGAs), Application Specific Integrated Circuits (ASICs), or the like. For example, the host 2000 may include a general purpose processor, a dedicated processor, and/or an application processor. The host 2000 may be a processor, or an electronic device, or a system that includes a processor.

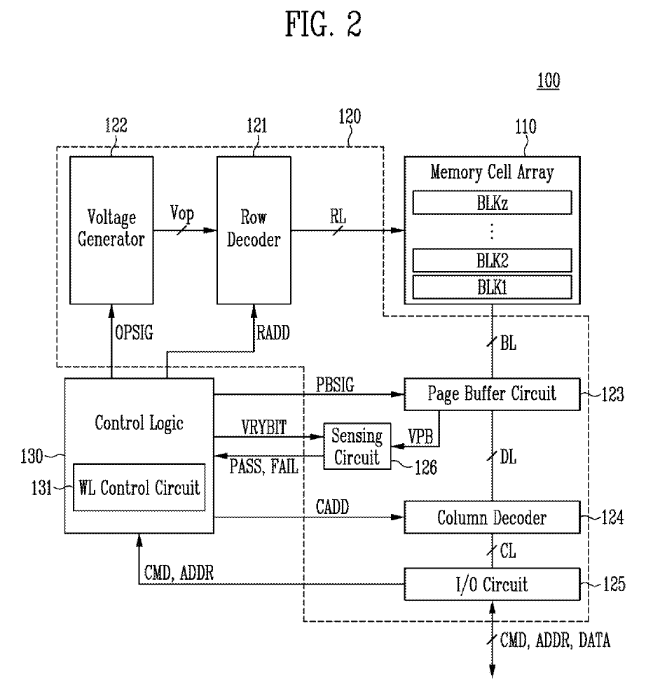

FIG. 2 is a diagram illustrating the structure of the memory device 100 according to an embodiment of the present disclosure.

Referring to FIG. 2, the memory device 100 may include a memory cell array 110, a peripheral circuit 120, and control logic 130.

The memory cell array 110 may include a plurality of memory blocks BLK1 to BLKz. The plurality of memory blocks BLK1 to BLKz may be coupled to a row decoder 121 via row lines RL. The plurality of memory blocks BLK1 to BLKz may be coupled to a page buffer circuit 123 via bit lines BL. Each of the plurality of memory blocks BLK1 to BLKz may include a plurality of memory cells. According to an embodiment, the plurality of memory cells may be non-volatile memory cells.

According to an embodiment, memory cells coupled to the same word line may be referred to as one page. Thus, a memory block may include a plurality of pages.

The row lines RL may include at least one source select line, a plurality of word lines, and at least one drain select line.

Each of the memory cells included in the memory cell array 110 may be configured as a Single Level Cell (SLC) that stores one data bit, a Multi-Level Cell (MLC) that stores two data bits, a Triple Level Cell (TLC) that stores three data bits, or a Quadruple Level Cell (QLC) that stores four data bits.

The peripheral circuit 120 may perform a program operation, a read operation, or an erase operation on a selected region of the memory cell array 110 under control of the control logic 130. The peripheral circuit 120 may drive the memory cell array 110. For example, the peripheral circuit 120 may apply various operating voltages to the row lines RL and the bit lines BL or may discharge the applied voltages under control of the control logic 130. For example, the peripheral circuit 120 may perform a sensing operation on the memory cells coupled to the selected word line among the plurality of memory cells by applying different voltages to the selected word line and the unselected word lines among the plurality of word lines.

The peripheral circuit 120 may include the row decoder 121, a voltage generator 122, the page buffer circuit 123, a column decoder 124, an input/output circuit 125, and a sensing circuit 126.

The row decoder 121 may be coupled to the memory cell array 110 via the row lines RL. The row lines RL may include one or more source select lines, a plurality of word lines, and one or more drain select lines. According to an embodiment, the word lines may include normal word lines and dummy word lines. According to an embodiment, the row lines RL may include a pipe select line.

The row decoder 121 may decode a row address RADD received from the control logic 130. The row decoder 121 may select at least one memory block of the memory blocks BLK1 to BLKz based on the decoded address. The row decoder 121 may apply voltages generated by the voltage generator 122 to at least one word line according to the decoded address. For example, the row decoder 121 may apply the voltages generated by the voltage generator 122 to at least one word line of the selected memory block.

According to an embodiment, during a program operation, the row decoder 121 may apply a program voltage to the selected word line and a program pass voltage at a level lower than that of the program voltage to the unselected word lines.

According to an embodiment, during a program verify operation, the row decoder 121 may apply a verify voltage to the selected word line and a verify pass voltage higher than the verify voltage to the unselected word lines.

According to an embodiment, during a read operation, the row decoder 121 may apply a read voltage to the selected word line and a read pass voltage higher than the read voltage to the unselected word lines.

According to an embodiment, an erase operation of the memory device 100 may be performed in units of memory blocks. During the erase operation, the row decoder 121 may select one memory block based on a decoded address. During the erase operation, the row decoder 121 may apply a ground voltage to word lines coupled to the selected memory block.

The voltage generator 122 may operate in response to control from the control logic 130. The voltage generator 122 may generate a plurality of voltages from an external power supply voltage supplied to the memory device 100. For example, the voltage generator 122 may generate a plurality of operation voltages Vop used for program, read, and erase operations in response to an operation signal OPSIG. For example, the voltage generator 122 may generate a program voltage, a verify voltage, a pass voltage, a read voltage, and an erase voltage in response to control from the control logic 130.

According to an embodiment, the voltage generator 122 may generate an internal power supply voltage by regulating an external power supply voltage. The internal power supply voltages generated by the voltage generator 122 may be used as operation voltages of the memory device 100. For example, the generated operation voltages may be supplied to the memory cell array 110 by the row decoder 121.

The page buffer circuit 123 may include a plurality of page buffers. The plurality of page buffers may be coupled to the memory cell array 110 via the bit lines BL, respectively. The plurality of page buffers may operate in response to control from the control logic 130. For example, the plurality of page buffers may operate in response to page buffer control signals PBSIG. For example, the plurality of page buffers may temporarily store data received through the bit lines BL or may sense voltages or currents in the bit lines BL during a read operation or a verify operation.

According to an embodiment, during a program operation, the plurality of page buffers may transfer data DATA received by the input/output circuit 125 to the selected memory cells via the bit lines BL when the program voltage is applied to the selected word line. The memory cells of the selected page may be programmed according to the transferred data DATA. During a program verify operation, the plurality of page buffers may read page data by sensing voltages or currents received from the selected memory cells via the bit lines BL.

According to an embodiment, during a read operation, the plurality of page buffers may read the data DATA via the bit lines BL from the memory cells of the selected page, and may output the read data DATA to the input/output circuit 125 under control of the column decoder 124.

According to an embodiment, during an erase operation, the plurality of page buffers may float the bit lines BL or may apply an erase voltage.

The column decoder 124 may transfer data between the input/output circuit 125 and the page buffer circuit 123 in response to a column address CADD. For example, the column decoder 124 may transfer data to and from the plurality of page buffers via data lines DL, or may transfer data to and from the input/output circuit 125 via column lines CL.

The input/output circuit 125 may transfer commands CMD and addresses ADDR received from the memory controller of FIG. 1 to the control logic 130, or may transfer the data DATA to and from the column decoder 124.

During a read operation or a verify operation, the sensing circuit 126 may generate a reference current in response to an allowable bit signal VRYBIT, and may output a pass signal PASS or a fail signal FAIL by comparing a pass/fail sensing voltage VPB received from the page buffer circuit 123 with a reference voltage generated by the reference current.

The control logic 130 may control the peripheral circuit 120 by outputting the operation signal OPSIG, the row address RADD, the page buffer control signals PBSIG, and the allowable bit VRYBIT in response to the commands CMD and the addresses ADDR. For example, the control logic 130 may control a read operation of the selected memory block in response to a sub-block read command and address. The control logic 130 may control an erase operation of the selected sub-block included in the selected memory block in response to the sub-block erase command and address. The control logic 130 may determine whether the verify operation passed or failed in response to the pass signal PASS or the fail signal FAIL.

The control logic 130 may control the operation of the peripheral circuit 120 to apply voltages to the plurality of word lines. According to an embodiment, the control logic 130 may include the word line control circuit 131. According to an embodiment, the word line control circuit 131 may be located externally to the control logic 130. The word line control circuit 131 may output the operation signal OPSIG that controls the voltages applied to the word lines, and the voltage generator 122 may generate the operation voltages Vop based on the operation signal OPSIG.

According to an embodiment, the word line control circuit 131 may control operation of the peripheral circuit 120 to apply voltages to the word lines. For example, during a sensing operation, the word line control circuit 131 may control voltages applied to the selected word line and the unselected word lines. For example, during an equalizing operation, the word line control circuit 131 may control voltages applied to the selected word line and the unselected word lines. For example, the word line control circuit 131 may control the peripheral circuit 120 to apply the same equalizing voltage to the selected word line and the unselected word lines during an equalizing operation. For example, each of the read operation and the verify operation may include a sensing operation and an equalize operation. For example, each of the read voltage and the verify voltage may include a sensing voltage and an equalize voltage.

According to an embodiment, the word line control circuit 131 may determine, based on the magnitude of the sensing voltage applied to the selected word line during the sensing operation, an equalizing time period during which the equalizing voltage is applied to the plurality of word lines during the equalizing operation. For example, based on the magnitude of the sensing voltage, the word line control circuit 131 may determine different equalizing time periods. For example, a longer equalizing time period may be determined for a smaller magnitude of the sensing voltage, whereas a shorter equalizing time period may be determined for a larger magnitude of the sensing voltage. For example, the memory controller 200 of FIG. 1 or the control logic 130 may determine the equalizing time period based on the magnitude of the sensing voltage and the degree of channel negative boosting.

According to an embodiment, the word line control circuit 131 may determine the equalizing time period based on the last-applied voltage level during the sensing operation. For example, the sensing voltage may include a plurality of voltage levels. Each of the plurality of memory cells may have a plurality of threshold voltage states, and the plurality of voltage levels may be voltages that distinguish between the plurality of threshold voltage states. For example, the word line control circuit 131 may determine a longer equalizing time period when the last-applied voltage level is smaller. For example, the word line control circuit 131 may determine a shorter equalizing time period when the last-applied voltage level is larger.

According to an embodiment, each of the selected memory cells may store a plurality of data bits, and the word line control circuit 131 may determine different equalizing time periods for the each of the plurality of data bits. For example, the equalizing time period for a first data bit may differ from the equalizing time period for a second data bit of the plurality of data bits.

According to an embodiment, during a first sensing operation that senses the first data bit and a second sensing operation that senses the second data bit, the word line control circuit 131 may control the peripheral circuit 120 to apply an equalizing voltage to the plurality of word lines for different equalizing time periods. For example, the word line control circuit 131 may control the peripheral circuit 120 to apply a first sensing voltage to the selected word line during the first sensing operation and a second sensing voltage to the selected word line during the second sensing operation. For example, the memory controller 200 of FIG. 1 or the control logic 130 may determine a first equalizing time period during which the equalizing voltage is applied to the plurality of word lines after the first sensing operation based on the magnitude of the first sensing voltage and a degree of channel negative boosting. Based on the comparison of the first sensing voltage and the second sensing voltage, the word line control circuit 131 may determine a second equalizing time period during which the equalizing voltage is applied to the plurality of word lines after the second sensing operation.

For example, the first sensing voltage may include at least one of the pluralities of voltage levels to identify the plurality of threshold voltage levels of the respective plurality of memory cells. For example, values of the plurality of data bits stored by the plurality of memory cells may be determined based on the plurality of threshold voltage states of the plurality of memory cells. For example, the second sensing voltage may include at least one of the pluralities of voltage levels. For example, the word line control circuit 131 may determine the second equalizing time period based on a comparison of a first voltage level lastly applied during the first sensing operation and a second voltage level lastly applied during the second sensing operation. The first voltage level may be the lowest among the last-applied voltage levels during each of the plurality of sensing operations for sensing the plurality of data bits stored in the plurality of memory cells. For example, the first voltage level may be lower than the second voltage level, and the second equalizing time period may be shorter than the first equalizing time period.

According to an embodiment, the word line control circuit 131 may determine a time during which the voltage value of the selected word line reaches a reference voltage value as an equalizing time period. For example, the word line control circuit 131 may determine the reference voltage value to be a voltage value of the selected word line at which an equalizing voltage is applied to the selected word line during the first equalizing time period after the first sensing operation. For example, the first sensing voltage may include at least one of the plurality of voltage levels to identify the plurality of threshold voltage levels, and the word line control circuit 131 may determine the voltage of the selected word line as the reference voltage value when the equalizing voltage is applied to the selected word line during the first equalizing time period after the first sensing level is last applied to the selected word line among the voltage levels included in the first sensing voltage.

For example, the word line control circuit 131 may determine the reference voltage value based on the first voltage level last applied to the selected word line during the first sensing operation. For example, the first voltage level may be the lowest among the last-applied voltage levels in each of the plurality of sensing operations for sensing the plurality of data bits stored in the plurality of memory cells. For example, the word line control circuit 131 may determine the reference voltage value based on the lowest voltage level among the plurality of voltage levels to identify the plurality of threshold voltage states. For example, the memory controller 200 of FIG. 1 or the control logic 130 may determine the reference voltage value based on the first voltage level and the degree of the channel negative boosting.

For example, the word line control circuit 131 may determine a time during which a voltage value of the selected word line reaches a reference voltage value from the second sensing voltage as the second equalizing time period. For example, the second sensing voltage may include at least one of a plurality of voltage levels to identify a plurality of threshold voltage states, and the word line control circuit 131 may determine a time during which the second voltage level last applied among the voltage levels included in the second sensing voltage reaches the reference voltage value as the second equalizing time period.

By determining the equalizing time period based on the magnitude of the sensing voltage, the time taken for a read operation or a verify operation of the memory device 100 may be reduced. For example, as the equalizing time period for the equalizing operation to prevent the channel negative boosting is reduced, the time to perform the read operation or the verify operation may be reduced.

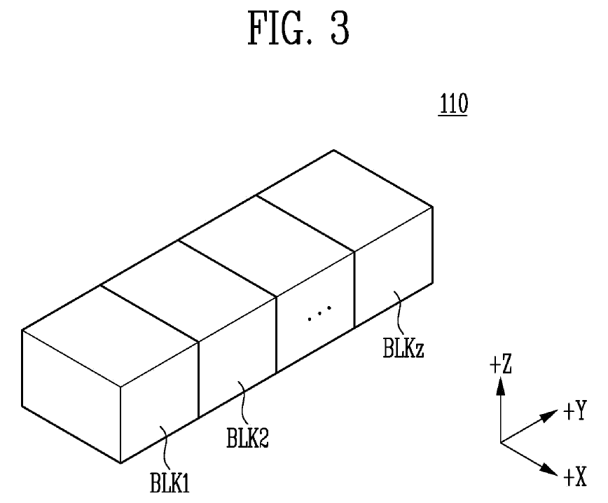

FIG. 3 is a diagram illustrating an embodiment of the memory cell array 110, for example, as shown in FIG. 2.

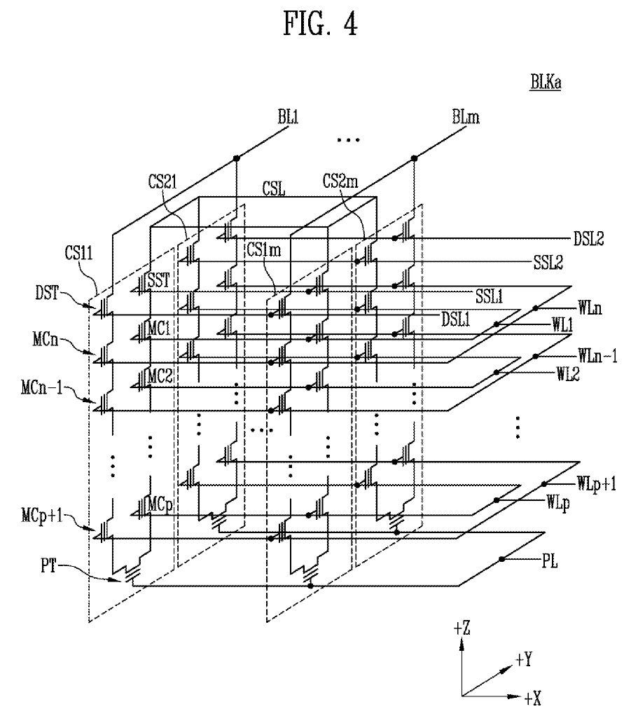

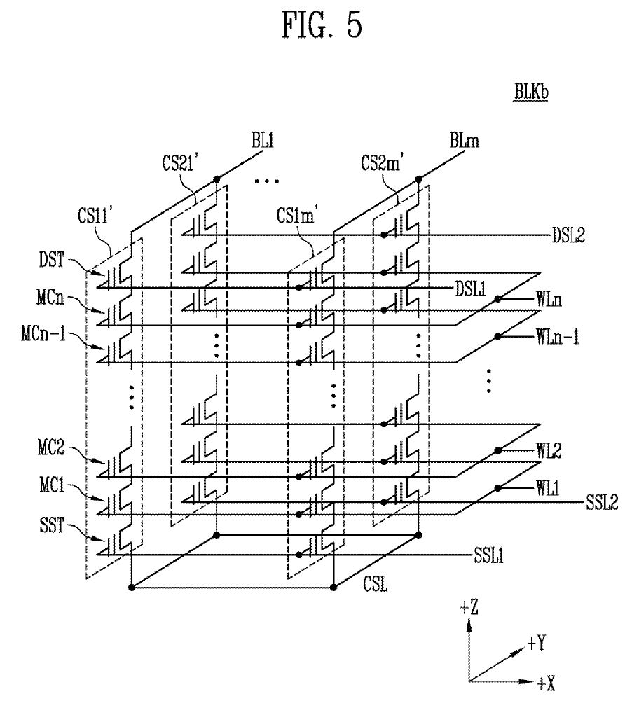

Referring to FIG. 3, the memory cell array 110 may include the plurality of memory blocks BLK1 to BLKz. Each memory block may have a three-dimensional structure. Each memory block may include a plurality of memory cells stacked on a substrate. The plurality of memory cells may be arranged along an +X direction, a +Y direction, and a +Z direction. The structure of each memory block is described with reference to FIGS. 4 and 5.

FIG. 4 is a diagram illustrating an embodiment of a memory block BLKa among the memory blocks BLK1 to BLKz, for example, as shown in FIG. 3.

Referring to FIG. 4, the memory block BLKa may include a plurality of cell strings CS11 to CS1m and CS21 to CS2m. According to an embodiment, each of the plurality of cell strings CS11 to CS1m and CS21 to CS2m may be formed in a U shape. Within the memory block BLKa, m cell strings may be arranged in a row direction indicated in +X direction in FIG. 4. Although two cell strings are shown arranged in a column direction indicated in +Y direction in FIG. 4, this is for simplicity of illustration, it will be understood that three or more cell strings are arranged in the column direction.

Each of the plurality of cell strings CS11 to CS1m and CS21 to CS2m may include at least one source select transistor SST, a first memory cell MC1 to an nth memory cell MCn, a pipe transistor PT, and at least one drain select transistor DST.

The source select transistor SST of each cell string may be coupled between a common source line CSL and memory cells MC1 to MCp.

According to an embodiment, source select transistors of cell strings arranged in the same row may be coupled to a source select line that extends in the row direction, and source select transistors of cell strings arranged in different rows may be coupled to different source select lines. For example, source select transistors of the cell strings CS11 to CS1m in a first row may be coupled to a first source select line SSL1, and source select transistors of the cell strings CS21 to CS2m in a second row may be coupled to a second source select line SSL2.

According to an embodiment, the source select transistors of the cell strings CS11 to CS1m and CS21 to CS2m may be commonly coupled to one source select line.

The memory cells MC1 to MCn of each cell string may be coupled between the source select transistor SST and the drain select transistor DST.

The memory cells MC1 to MCn may be divided into first memory cell MC1 to pth memory cell MCp and (p+1) memory cells MCp+1 to nth memory cell MCn. The memory cells MC1 to MCp may be arranged sequentially in an opposite direction to the +Z direction and may be coupled in series between the source select transistor SST and the pipe transistor PT. The (p+1) memory cell MCp+1 to the nth memory cell MCn are arranged sequentially in the Z direction and may be coupled in series between the pipe transistor PT and the drain select transistor DST. The memory cells MC1 to MCp and the memory cells MCp+1 to MCn may be coupled via the pipe transistor PT. Gates of the memory cells MC1 to MCn of each cell string may be coupled to a first word lines WL1 to an nth word line WLn, respectively.

A gate of the pipe transistor PT of each cell string may be coupled to a pipe line PL.

A drain select transistor DST of each cell string may be coupled between a corresponding bit line and the memory cells MCp+1 to MCn. Cell strings arranged in the row direction may be coupled to a drain select line extending in the row direction. Drain select transistors of the cell strings CS11 to CS1m in the first row may be coupled to a first drain select line DSL1. Drain select transistors of the cell strings CS21 to CS2m in the second row may be coupled to a second drain select line DSL2.

Cell strings arranged in the column direction may be coupled to a bit line that extends in the column direction. For example, cell strings CS11 and CS21 in a first column are coupled to a first bit line BL1. Cell strings CS1m and CS2m of an mth column may be coupled to an mth bit line BLm.

Within cell strings arranged in the row direction, memory cells coupled to the same word line may be grouped as one page. For example, among the cell strings CS11 to CS1m of the first row, the memory cells coupled to the first word line WL1 may be grouped as one page. The memory cells coupled to the first word line WL1 of the cell strings CS21 to CS2m of the second row may be grouped as another page. By selecting one of the drain select lines DSL and DSL2, the cell strings arranged in one row direction may be selected. By selecting one of the word lines WL1 to WLn, a page of one of the selected cell strings may be selected. For example, when memory cells coupled to the same word line may be grouped as one page, the memory cells may be single level cells (SLCs) where one data bit is stored per cell.

According to an embodiment, memory cells that are coupled to the same word line within string cells arranged in a row direction may be grouped as a plurality of pages. For example, when the memory cells store a plurality of data bits, the plurality of data bits may be stored on the plurality of pages of the memory cells, respectively. In the example of a Multi-Level Cell MLC where a single memory cell stores two data bits, memory cells coupled to the same word line may form two pages. In the example of a Triple Level Cell TLC where a single memory cell stores three data bits, memory cells coupled to the same word line may form three pages. In the example of a Quadruple Level Cell (QLC), where a single memory cell stores four data bits, memory cells coupled to the same word line may form four pages.

FIG. 5 is a diagram illustrating an embodiment of a memory block BLKb among the memory blocks BLK1 to BLKz, for example, as shown in FIG. 3.

Referring to FIG. 5, the memory block BLKb may include a plurality of cell strings CS11’ to CS1m’ and CS21’ to CS2m’. Each of the plurality of cell strings CS11’ to CS1m’ and CS21’ to CS2m’ may extend along the +Z direction. Each of the plurality of cell strings CS11’ to CS1m’ and CS21’ to CS2m’ may include at least one source select transistor SST, the memory cells MC1 to MCn, and at least one drain select transistor DST stacked on a substrate (not shown) below a memory block BLK1’.

The source select transistor SST of each cell string may be coupled between the common source line CSL and the memory cells MC1 to MCn. Source select transistors of cell strings arranged in the same row may be coupled to the same source select line. Source select transistors of the cell strings CS11’ to CS1m’ arranged in a first row may be coupled to the first source select line SSL1. Source select transistors of the cell strings CS21’ to CS2m’ arranged in a second row may be coupled to the second source select line SSL2. In an embodiment, the source select transistors of the cell strings CS11’ to CS1m’ and CS21’ to CS2m’ may be commonly coupled to a single source select line.

The first to nth memory cells MC1 to MCn of each cell string may be coupled in series between the source select transistor SST and the drain select transistor DST. Gates of the memory cells MC1 to MCn may be coupled to the first to nth word lines WL1 to WLn, respectively.

The drain select transistor DST of each cell string may be coupled between the corresponding bit line and the memory cells MC1 to MCn. Drain select transistors of cell strings arranged in the row direction may be coupled to a drain select line extending in the row direction. The drain select transistors of the cell strings CS11’ to CS1m’ of the first row may be coupled to the first drain select line DSL1. Drain select transistors of the cell strings CS21’ to CS2m’ of the second row may be coupled to the second drain select line DSL2.

The memory block BLKb in FIG. 5 may be an equivalent circuit similar to the memory block BLKa in FIG. 4 except each cell string does not include the pipe transistor PT in memory block BLKb.

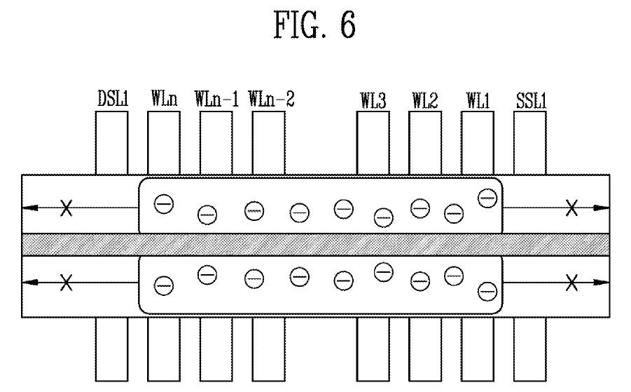

FIG. 6 is a diagram illustrating channel negative boosting occurring in accordance with an embodiment of the present disclosure.

Referring to FIGS. 4 and 6, FIG. 6 illustrates the first drain select line DSL1, the first source select line SSL1, and the word lines WL1 to WLn between the first drain select line DSL1 and the first source select line SSL1 of FIG. 4. The descriptions of FIG. 6 may be applicable to the memory block structure of FIG. 5 as well as the memory block structure of FIG. 4.

According to an embodiment, the memory device 100 of FIG. 1 may apply a turn-off voltage to the first drain select line DSL1 and the first source select line SSL1 for a function such as terminating a sensing operation. A voltage that turns off transistors coupled to the first drain select line DSL1 and the first source select line SSL1 may be applied to the first drain select line DSL1 and the first source select line SSL1.

According to an embodiment, when the turn-off voltage is applied to the first drain select line DSL1 and the first source select line SSL1, a channel of the word lines WL1 to WLn may be floated. Thus, by applying the turn-off voltage to the first drain select line DSL1 and the first source select line SSL1, the memory cells coupled to the word lines WL1 to WLn and the transistors coupled to the first drain select line DSL1 and the first source select line SSL1 may be separated from each other.

When the channel of the word lines WL1 to WLn is floated, charges in the channel of the first to nth word lines WL1 to WLn may be isolated, and the voltage at the channel may change to a negative value. The phenomenon where the voltage of the channel changes to a negative value is referred to as channel negative boosting. For example, channel negative boosting may result in undesirable negative channel voltage in unselected memory cells.

After the sensing operation, such channel negative boosting may be prevented by performing an equalizing operation to recover the voltage of the channel that is a negative voltage. By performing the equalizing operation, the time to perform a read operation or a verify operation that includes the sensing operation may be increased. In accordance with an embodiment, by reducing the time to perform the equalizing operation, the time for the memory device to perform the read operation or the verify operation may be reduced.

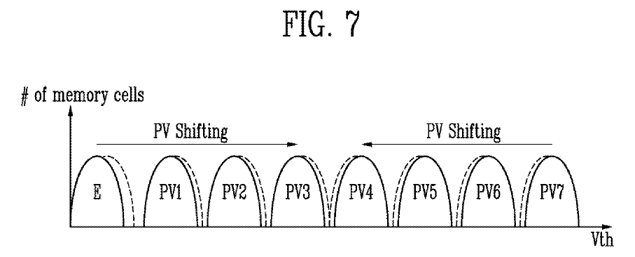

FIG. 7 is a diagram illustrating a shift in threshold voltage distribution due to channel negative boosting according to an embodiment of the present disclosure.

In FIG. 7, the horizontal axis represents threshold voltages Vth of memory cells, and the vertical axis represents the quantity or number # of memory cells.

Referring to FIG. 7, the effects of channel negative boosting are shown.

Memory cells may include a plurality of threshold voltage states. For example, each of the memory cells may be in an erase state E or one of a first program state PV1 to a seventh program state PV7. FIG. 7 illustrates a change in threshold voltage distribution when the memory cells are programmed as triple level cells TLCs.

The shifting of FIG. 7 also applies to memory cells that are programmed as Single Level Cell (SLCs), Multi-Level Cell (MLCs), or Quadruple Level Cells (QLCs), although the quantity of states differs from the quantity shown in FIG. 7.

According to an embodiment, channel negative boosting may cause hot carrier injection HCI. As hot carrier injection HCI occurs, PV shifting of the threshold voltage distribution may occur.

Referring to FIGS. 4 and 5, as the drain select transistors and the source select transistors are turned off, charges in the channel are isolated. As the isolated charges are moved to the memory cells, threshold voltages of memory cells in lower program states may be increased. For example, the threshold voltages of the memory cells in the erase state and first program state PV1 to the third program state PV3 may be increased, referred to as PV Shifting.

As the charges in the channel are isolated, the threshold voltage of the memory cells in the higher program states may be reduced as the charges trapped in the memory cells are shifted into the channel. For example, the threshold voltage of the memory cells in the fourth program state P4 to the seventh program state P7 may be reduced, referred to as PV Shifting.

Due to channel negative boosting, the threshold voltage distribution of the memory cells is changed, which may degrade the reliability of the data programmed into the memory cells.

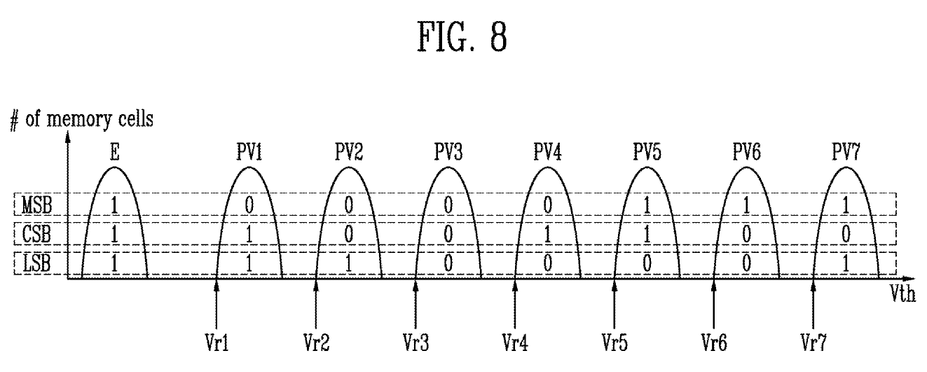

FIG. 8 is a diagram illustrating a threshold voltage distribution of memory cells and corresponding data bits according to an embodiment of the present disclosure.

In FIG. 8, the horizontal axis represents threshold voltages Vth of memory cells, and the vertical axis represents the quantity or number # of memory cells.

FIG. 8 illustrates a change in threshold voltage distribution when the memory cells are programmed as triple level cells TLCs. Referring to FIG. 8, the threshold voltages of the plurality of memory cells may be raised to one of the erase state E and first program state PV1 to seventh program state PV7 by a program operation. For example, during a program verify operation, the memory device 100 may verify whether a threshold voltage of each of the selected memory cells coupled to the selected word line is greater than a voltage applied to the selected word line. During the program verify operation, the memory device 100 may apply a program verify voltage to the selected word line coupled to the selected memory cells and may sense the data stored in the selected memory cells by detecting a change in current in the bit lines coupled to the selected memory cells to verify whether the selected memory cells are programmed to a target threshold voltage value or greater during the program operation.

According to an embodiment, the memory device 100 may perform a read operation to acquire data stored in the memory cells. For example, during the read operation, the memory device 100 may determine whether a threshold voltage of each of the selected memory cells coupled to the selected word line is greater than a voltage applied to the selected word line. When the memory device 100 applies a sensing voltage to the selected word line coupled to the selected memory cells among the plurality of memory cells, the memory device 100 may sense the data stored in the selected memory cell by sensing a change in current in the bit line coupled to the selected memory cell. Data bits stored in the memory cells may vary depending on program states of the memory cells. For example, the memory cells may store a respective data bit in each memory cell based on its threshold voltage, which is determined to correspond to one of the erase state E and the first program state PV1 to the seventh program state PV7.

According to an embodiment, the memory device 100 may perform a sensing operation for each of the plurality of pages using sensing voltages including at least one of a plurality of voltage levels. For example, a read operation of the memory device 100 may include a sensing operation for each of the plurality of pages. The plurality of pages may include a least significant bit LSB page, a central significant bit CSB page, and a most significant MSB page.

According to an embodiment, the memory device 100 may apply a first sensing voltage to the selected word line to perform a sensing operation on the LSB page. For example, the first sensing voltage may include a third voltage level Vr3 and a seventh voltage level Vr7. For example, when the LSB page corresponding to the erase state E and the first program state PV1 to the seventh program state PV7 is 11100001, the sensing operation on the LSB page may be performed using the third voltage level Vr3 and the seventh voltage level Vr7 to distinguish between 1 and 0.

According to an embodiment, the memory device 100 may apply a second sensing voltage to the selected word line to perform a sensing operation on the CSB page. For example, the second sensing voltage may include a second voltage level Vr2, a fourth voltage level Vr4, and a sixth voltage level Vr6. For example, when the CSB page corresponding to the erase state E and the first program state PV1 to the seventh program state PV7 is 11001100, the sensing operation for the CSB page may be performed using the second voltage level Vr2, the fourth voltage level Vr4, and the sixth voltage level Vr6 to distinguish between 1 and 0.

According to an embodiment, the memory device 100 may apply a third sensing voltage to the selected word line to perform a sensing operation on the MSB page. For example, the third sensing voltage may include a first voltage level Vr1 and a fifth voltage level Vr5. For example, when the MSB page corresponding to the erase state E and the program states PV1 to PV7 is 10000111, the sensing operation on the MSB page may be performed using first voltage level Vr1 and the fifth voltage level Vr5 to distinguish between 1 and 0.

In an embodiment, data bits may be stored in the LSB page, the CSB page, and the MSB page in a different manner than shown in FIG. 8. The sensing voltages used to perform the sensing operations for the LSB pages, CSB pages, and MSB pages may vary. For example, although two voltage levels of the first sensing voltage for the read operation on the LSB page are shown in FIG. 8, the read operation may be performed using three voltage levels depending on the bits included in the LSB page. The size and quantity of voltage levels of sensing voltages to distinguish between 1 and 0 may vary depending on the bits included in the LSB page, the CSB page, and the MSB page.

Although sensing voltages for a plurality of pages are described in the present specification as being used as shown in FIG. 8, it is understood that the sensing voltages for performing sensing operations on the plurality of pages may vary according to various embodiments of the present disclosure.

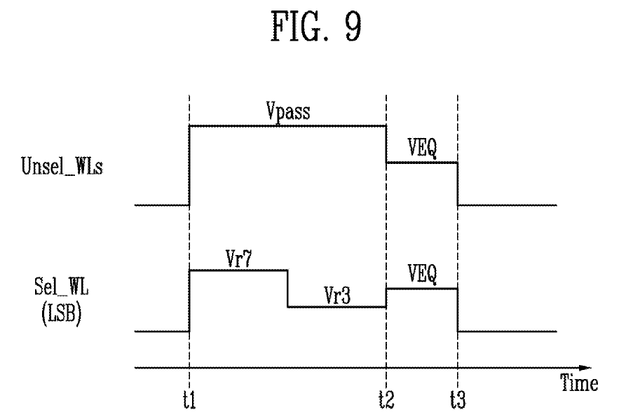

FIG. 9 is a timing diagram illustrating voltages applied to unselected word lines and a selected word line during a sensing operation and an equalizing operation according to an embodiment of the present disclosure, for example, with reference to FIGS. 1 and 2.

Referring to FIG. 9, as in FIG. 8, the when memory cells are programmed as trip-level cells and the LSB page is 11100001, a read operation for the LSB page may be performed using a voltage of the third voltage level Vr3 and a voltage of the seventh voltage level Vr7 to distinguish between 1 and 0.

During a time period from t1 to t2, the memory device 100 may perform a sensing operation. For example, the memory device 100 may apply a pass voltage Vpass to unselected word lines Unsel_WLs and may apply a first sensing voltage to a selected word line Sel_WL. For example, the first sensing voltage may include a voltage of the seventh voltage level Vr7 and a voltage of the third voltage level Vr3 applied sequentially.

During a time period from t2 to t3, the memory device 100 may perform an equalizing operation. For example, the memory device 100 may apply an equalizing voltage VEQ to the selected word line Sel_WL and the unselected word lines Unsel_WLs.

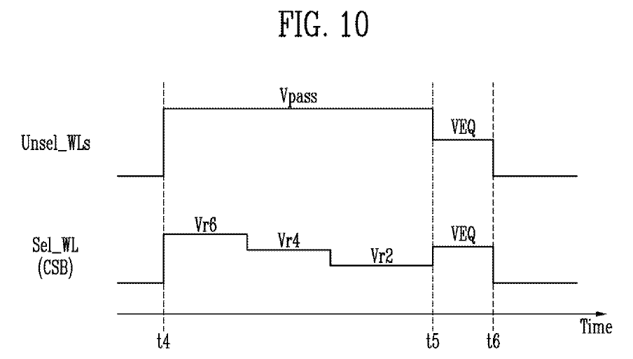

FIG. 10 is a timing diagram illustrating voltages applied to the unselected word lines and the selected word line during a sensing operation and an equalizing operation for a CSB page according to an embodiment of the present disclosure, for example, with reference to FIGS. 1 and 2.

Referring to FIG. 10, as in FIG. 8, when the memory cells are programmed as triple-level cells and the CSB page is 11001100, a read operation for the CSB page may be performed using the voltages of the second voltage level Vr2, the fourth voltage level Vr4, and the sixth voltage level Vr6 to distinguish between 1 and 0.

During a time period from t4 to t5, the memory device 100 may perform a sensing operation. For example, the memory device 100 may apply the pass voltage Vpass to the unselected word lines Unsel_WLs and may apply a second sensing voltage to the selected word line Sel_WL. For example, the second sensing voltage may include voltages of the sixth voltage level Vr6, the fourth voltage level Vr4, and the second voltage level Vr2 applied sequentially.

During a time period from t5 to t6, the memory device 100 may perform an equalizing operation. For example, the memory device 100 may apply the equalizing voltage VEQ to the selected word line Sel_WL and the unselected word lines Unsel_WLs.

FIG. 11 is a timing diagram illustrating voltages applied to the unselected word lines and the selected word line during a sensing operation and an equalizing operation for an MSB page according to an embodiment of the present disclosure, for example, with reference to FIGS. 1 and 2.

Referring to FIG. 11, as in FIG. 8, when the memory cells are programmed as triple-level cells and the MSB page is 10000111, a read operation for the CSB page may be performed using the voltages of the first voltage level Vr1 and the fifth voltage level Vr5 to distinguish between 1 and 0.

During a time period from t7 to t8, the memory device 100 may perform a sensing operation. For example, the memory device 100 may apply the pass voltage Vpass to the unselected word lines Unsel_WLs and may apply a third sensing voltage to the selected word line Sel_WL. For example, the third sensing voltage may include voltages of the fifth voltage level Vr5 and the first voltage level Vr1 applied sequentially.

During a time period from t8 to t9, the memory device 100 may perform an equalizing operation. For example, the memory device 100 may apply the equalizing voltage VEQ to the selected word line Sel_WL and the unselected word lines Unsel_WLs.

Referring to FIGS. 9 to 11, the read operation for the memory cells of the memory device 100 may include a sensing operation and an equalizing operation for each of the LSB page, the CSB page, and the MSB page. For example, when the memory device 100 performs a read operation on the memory cells, the sensing operation and the equalizing operation for each of the LSB page, the CSB page, and the MSB page may be performed sequentially.

According to an embodiment, the equalizing time period for the equalization operation for each of the LSB page, the CSB page, and the MSB page may vary. For example, the time period from t2 to t3 in FIG. 8, the time period from t5 to t6 in FIG. 9, and the time period from t8 to t9 in FIG. 10 may be different from each other.

According to an embodiment, the word line control circuit 131 may determine the equalizing time period based on the magnitude of the sensing voltage applied to the selected word line Sel_WL during the sensing operation. For example, the word line control circuit 131 may determine the equalizing time period based on a voltage level of a last-applied voltage during the sensing operation. For example, the word line control circuit 131 may determine the equalizing time period based on the lowest voltage level among the voltage levels of the last-applied voltages to the selected word line Sel_WL during the sensing operations of the plurality of pages. For example, the voltage level of the last-applied voltage applied to the selected word line Sel_WL during the sensing operation may be the third voltage level Vr3 for the LSB page, the second voltage level Vr2 for the CSB page, and the first voltage level Vr1 for the MSB page. The word line control circuit 131 may determine the equalizing time period based on the first voltage level Vr1 that is the lowest voltage level among the first voltage level Vr1, the second voltage level Vr2, and the third voltage level Vr3.

For example, based on a magnitude of the third sensing voltage applied during the sensing operation of the MSB page, such as the voltage level of the third sensing voltage, the word line control circuit 131 may determine a third equalizing time period during which the equalizing operation of the MSB page is performed. For example, based on the voltage of the first voltage level Vr1 that is last applied among the voltages included in the third sensing voltage, the word line control circuit 131 may determine the third equalizing time period. For example, the word line control circuit 131 may determine the third equalizing time period based on the degree of channel negative boosting according to the equalizing time period during which the equalizing voltage VEQ is applied to the selected word line Sel_WL after the voltage of the first voltage level Vr1 is applied.

For example, based on a comparison of the first sensing voltage and the third sensing voltage applied during the sensing operation of the LSB page, the word line control circuit 131 may determine a first equalizing time period during which the equalizing operation of the LSB page is performed. For example, based on a voltage of the first voltage level Vr1 and a voltage of the third voltage level Vr3 last applied among the voltages included in the first sensing voltage, the word line control circuit 131 may determine or may select the first equalizing time period. For example, based on a comparison result of the third voltage level Vr3 and the first voltage level Vr1, and the third equalizing time period, the word line control circuit 131 may determine or may select the first equalizing time period. For example, because the third voltage level Vr3 is larger than the first voltage level Vr1, the word line control circuit 131 may determine the first equalizing time period as shorter than the third equalizing time period.

For example, based on a comparison of the second sensing voltage and the third sensing voltage applied during the sensing operation of the CSB page, the word line control circuit 131 may determine a second equalizing time period during which the equalizing operation of the CSB page is performed. For example, based on a voltage of the second voltage level Vr2 that is last applied among the voltage levels included in the second sensing voltage, and a voltage of the first voltage level Vr1, the word line control circuit 131 may determine the second equalizing time period. For example, because the second voltage level Vr2 is smaller than the third voltage level Vr3, the second equalizing time period determined by the word line control circuit 131 may be longer than the third equalizing time period.

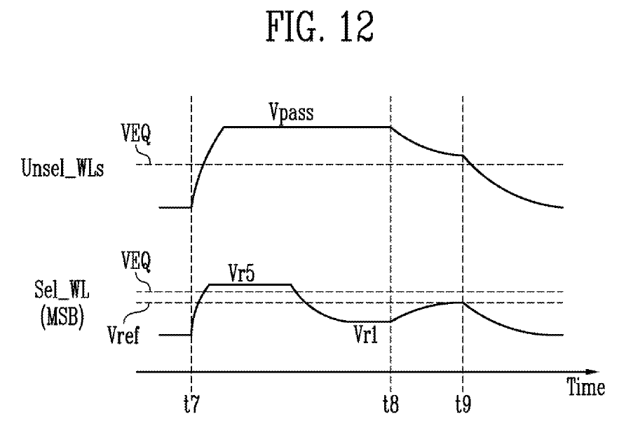

FIG. 12 is a timing diagram illustrating voltage changes on the unselected word lines and the selected word line during a sensing operation and an equalizing operation according to an embodiment of the present disclosure, for example, with reference to FIGS. 1 and 2.

Referring to FIG. 12, voltages applied to the unselected word lines Unsel_WLs and the selected word line Sel_WL may be different from voltages of the unselected word lines Unsel_WLs and the selected word line Sel_WL. For example, a delay may occur when the unselected word lines Unsel_WLs and the selected word line Sel_WL are charged or discharged to the voltage applied by the memory device 100.

For example, at a time t7, the voltage on the unselected word lines Unsel_WLs may be the pass voltage Vpass after an arbitrary delay after the pass voltage Vpass is applied to the unselected word lines Unsel_WLs. For example, at the time t7, the voltage of the fifth voltage level Vr5 may be applied to the selected word line Sel_WL and, after an arbitrary delay, the voltage of the selected word line Sel_WL may be the fifth voltage level Vr5. After the voltage of the first voltage level Vr1 is applied to the selected word line Sel_WL, after an arbitrary delay, the voltage of the selected word line Sel_WL may be the first voltage level Vr1.

At a time t8, after the equalizing voltage VEQ is applied to the unselected word lines Unsel_WLs and the selected word line Sel_WL, the voltages of the unselected word lines Unsel_WLsand the selected word line Sel_WL may be different from the equalizing voltage VEQ. For example, from time t9 forward, the equalizing voltage VEQ may not be applied, and the voltages of the unselected word lines Unsel_WLs and the selected word line Sel_WL may not be charged or discharged to the equalizing voltage VEQ. For example, the voltage of the selected word line Sel_WL may be charged up to a reference voltage Vref. For example, a value of the reference voltage Vref may be less than the voltage of the equalizing voltage VEQ.

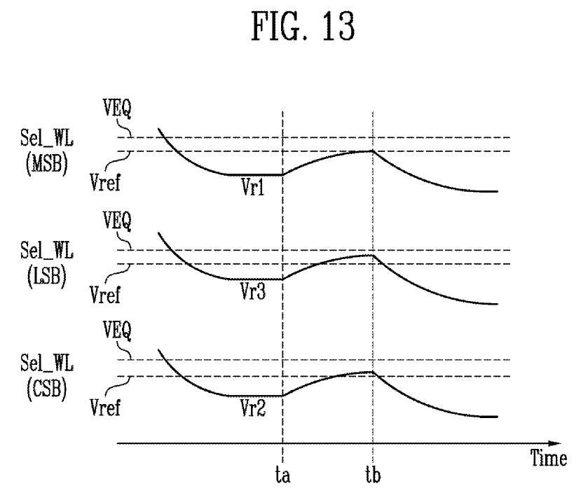

FIG. 13 is a timing diagram illustrating voltage changes on a selected word line during an equalizing operation for each of a plurality of pages according to an embodiment, for example, with reference to FIGS. 1 and 2.

Referring to FIG. 13, at a time period from ta to tb, during an equalizing operation for each of the plurality of pages, the memory device 100 may apply the equalizing voltage VEQ to the selected word line Sel_WL. For example, during the equalizing operation for each of the plurality of pages, the memory device 100 may apply the equalizing voltage VEQ to the selected word line Sel_WL during the same equalizing time period.

For example, at a time tb, the voltages of the selected word line Sel_WL during the equalizing operation for each of the plurality of pages may differ. For example, because the equalizing voltage is applied during the same time period, the voltages of the selected word line Sel_WL at the time tb may be different depending on the voltage level of the last-applied voltage during the sensing operation. For example, the voltage of the selected word line Sel_WL at the time tb may be larger when the voltage level of the voltage last applied during the sensing operation is large.

For example, during an equalizing operation for an MSB page, the voltage on the selected word line Sel_WL at the time tb may be equal to the value of the reference voltage Vref. For example, during the equalizing operation for the LSB page and the equalizing operation for the CSB page, the voltage of the selected word line Sel_WL at the time tb may be greater than the value of the reference voltage Vref. For example, the voltage of the selected word line Sel_WL at the time tb during the equalizing operation for the LSB page may be greater than the voltage of the selected word line Sel_WL at the time tb during the equalizing operation for the CSB page.

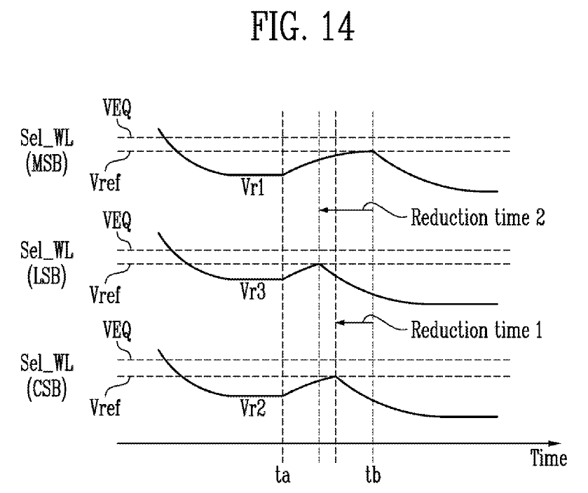

FIG. 14 is a timing diagram illustrating voltage changes on a selected word line during an equalizing operation for each of a plurality of pages according to an embodiment, for example, with reference FIGS. 1 and 2.

Referring to FIG. 14, the equalizing time period for the equalization operation for each of the LSB page, the CSB page, and the MSB page may differ.

According to an embodiment, the word line control circuit 131 may determine an equalizing time period based on a value of the reference voltage Vref. For example, the word line control circuit 131 may control the peripheral circuit 120 to apply the equalizing voltage VEQ to the selected word line Sel_WL until the voltage on the selected word line Sel_WL reaches the value of the reference voltage Vref after the sensing operation.

For example, the magnitude of the last-applied voltage during the sensing operation for the MSB page may be the first voltage level Vr1, the magnitude of the last-applied voltage during the sensing operation for the LSB page may be the third voltage level Vr3, and the magnitude of the last-applied voltage during the sensing operation for the CSB page may be the second voltage level Vr2.

For example, the word line control circuit 131 may determine a shorter equalizing time period when the voltage level of the last-applied voltage during the sensing operation is higher, and a longer equalizing time period when the voltage level of the last-applied voltage during the sensing operation is smaller. For example, the equalizing time period of the MSB page during which the voltage of the first voltage level Vr1 is last applied may be longer than the equalizing time period of the CSB page during which the voltage of the second voltage level Vr2 is last applied. For example, the equalizing time period of the CSB page during which the voltage of the second voltage level Vr2 is last applied may be longer than the equalizing time period of the LSB page during which the voltage of the third voltage level Vr3 is last applied. Compared to the equalizing time period of the MSB page, the equalizing time period of the CSB page may be reduced by a first reduction time 1. Compared to the equalizing time period of the MSB page, the equalizing time period of the LSB page may be reduced by a second reduction time 2. The second reduction time 2 may be greater than the first reduction time 1.

According to an embodiment, based on the lowest voltage level among the voltage levels of the last-applied voltage during the sensing operation for each of the plurality of pages, the word line control circuit 131 may determine the value of the reference voltage Vref. For example, based on the first voltage level Vr1, which is the voltage level of the last-applied voltage during the sensing operation for the MSB page, the word line control circuit 131 may determine the value of the reference voltage Vref. For example, when the equalizing voltage is applied to the selected word line Sel_WL at the voltage of the first voltage level Vr1 during the first equalizing time period, the voltage level reached may be determined as the value of the reference voltage Vref. For example, the memory controller 200 or the control logic 130 may determine the first equalizing time period based on the first voltage level Vr1 and the degree of channel negative boosting.

According to an embodiment, based on the lowest voltage level of the plurality of voltage levels to identify the plurality of threshold voltage levels of the memory cells, the word line control circuit 131 may determine the value of the reference voltage Vref. For example, referring to FIG. 8, based on the first voltage level Vr1, which is the lowest voltage level among the plurality of voltage levels Vr1 to Vr7 to identify the erase state E and the first to seventh program states PV1 to PV7, the word line control circuit 131 may determine the value of the reference voltage Vref. For example, the word line control circuit 131 may determine the voltage value of the selected word line Sel_WL to which the equalizing voltage is applied during the first equalizing time period from the first voltage level Vr1 as the value of the reference voltage Vref. For example, the memory controller 200 or the control logic 130 may determine the first equalizing time period based on the first voltage level Vr1 and the degree of channel negative boosting.

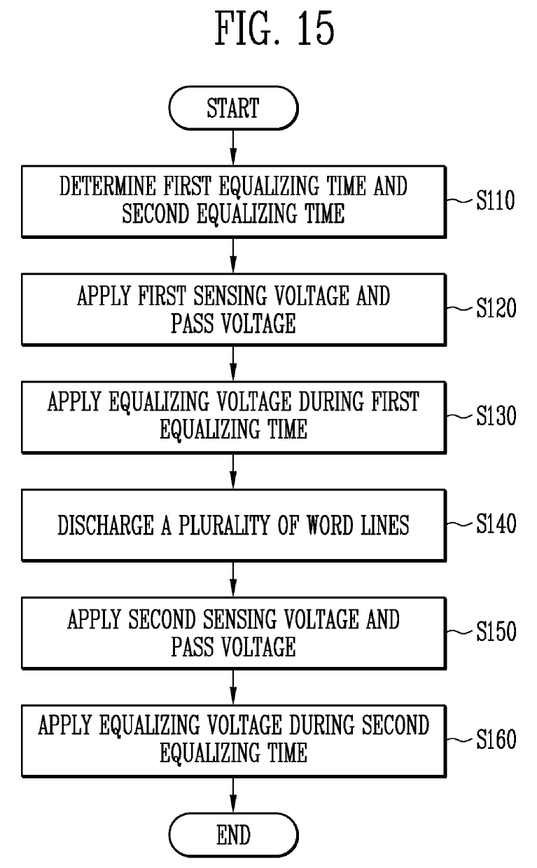

FIG. 15 is a flowchart of a method of performing an equalizing operation of a memory device according to an embodiment, for example, with reference to FIG. 1 and FIG. 2. The processes of the flowchart may be performed in a different order and may include fewer or additional processes than described and shown in FIG. 15.

At step S110, a first equalizing time period and a second equalizing time period may be determined. According to an embodiment, each of the selected memory cells may store a plurality of data bits. The word line control circuit 131 may determine different equalizing time periods for each of the plurality of data bits. For example, the plurality of data bits may include a first data bit and a second data bit, and the first equalizing time period of the first data bit may be different from the second equalizing time period of the second data bit.

The word line control circuit 131 may determine the first equalizing time period and may determine the second equalizing time period based on the first equalizing time period. For example, equalizing time periods for each of the plurality of data bits may be determined based on the first equalizing time period.

According to an embodiment, the memory device 100 may store information about sensing voltages used in the sensing operation for each of the plurality of data bits. For example, each of the sensing voltages may include a plurality of voltage levels. For example, the memory device 100 may store information about a first sensing voltage used in the sensing operation of the first data bit and a second sensing voltage used in the sensing operation of the second data bit. The memory device 100 may store information about voltage levels that the first sensing voltage includes and voltage levels that the second sensing voltage includes. For example, the first equalizing time period may be determined based on the first voltage level last applied in the process of applying the first sensing voltage. For example, the first voltage level may be the lowest voltage level among the voltage levels of the last-applied voltage during the process of applying each of the plurality of sensing voltages. For example, the first voltage level may be lower than the second voltage level last applied during the process of applying the second sensing voltage. For example, the first voltage level may be lower than the third voltage level last applied during the process of applying the third sensing voltage. For example, the word line control circuit 131 may determine the first equalizing time period based on the degree of the channel negative boosting. Depending on the time during which an equalizing voltage is applied to the selected word line from the first voltage level, the degree of the channel negative boosting may vary. For example, as the equalizing time period increases, channel negative boosting may decrease. The equalizing time period and the degree of channel negative boosting may be inversely proportional.

For example, the word line control circuit 131 may determine the second equalizing time period based on a comparison of the first sensing voltage and the second sensing voltage. For example, the word line control circuit 131 may determine the second equalizing time period based on the comparison between the first voltage level and the second voltage level. For example, the word line control circuit 131 may determine the second equalizing time as shorter than the first equalizing time period based on an extent to which the second voltage level is greater than the first voltage level. For example, the memory device 100 may store the second equalizing time period.

According to an embodiment, a voltage value at which the equalizing voltage is applied to the selected word line from the first sensing voltage during the first equalizing time period may be determined as a reference voltage value. For example, the word line control circuit 131 may determine a time during which the voltage value of the selected word line reaches the reference voltage value from the second voltage level as the second equalizing time period.

At step S120, he first sensing voltage and a pass voltage may be applied. For example, the word line control circuit 131 may be controlled to apply the pass voltage to an unselected word line of a plurality of word lines. For example, the word line control circuit 131 may be controlled to apply the first sensing voltage to the selected word line of the plurality of word lines. For example, the word line control circuit 131 may use information about the first sensing voltage and the pass voltage stored within the memory device 100. The word line control circuit 131 may control the first sensing voltage to sequentially apply voltage levels including the first sensing voltage to the selected word line. The memory device 100 may determine whether a threshold voltage of each of the memory cells coupled to the selected word line is greater than the voltage levels applied to the selected word line. For example, based on the voltage levels applied to the selected word line, the memory device 100 may determine which of a plurality of threshold voltage states the memory cells have.

At step S130, an equalizing voltage may be applied to the plurality of word lines during the first equalizing time period. For example, the word line control circuit 131 may be controlled to apply the equalizing voltage to the plurality of word lines during the first equalizing time period. For example, the word line control circuit 131 may use information about the equalizing voltage and the first equalizing time period stored within the memory device 100.

At step S140, the plurality of word lines may be discharged. For example, the word line control circuit 131 may be controlled to stop applying the equalizing voltage.

At step S150, the second sensing voltage and the pass voltage may be applied. For example, the word line control circuit 131 may be controlled to apply the pass voltage to an unselected word line of the plurality of word lines. For example, the word line control circuit 131 may be controlled to apply the second sensing voltage to the selected word line of the plurality of word lines. For example, the second sensing voltage may include different voltage levels from the voltage levels of the first sensing voltage. For example, the word line control circuit 131 may use information about the second sensing voltage and the pass voltage stored within the memory device 100.

At step S160, the equalizing voltage may be applied to the plurality of word lines during the second equalizing time period. For example, the word line control circuit 131 may be controlled to apply the equalizing voltage to the plurality of word lines during the second equalizing time period. For example, the word line control circuit 131 may use information about the equalizing voltage and the second equalizing time period stored within the memory device 100.

According to an embodiment, the equalizing voltage may be applied to the plurality of word lines until the voltage value of the selected word line reaches a reference voltage value from the voltage of the second voltage level. For example, the word line control circuit 131 may determine a time during which the voltage value of the selected word line reaches the reference voltage value from the voltage at the second voltage level as the second equalizing time period.

The sensing operation and the equalizing operation for each of the first data bit and the second data bit are described with reference to FIG. 15. Depending on the quantity of data bits included in the selected memory cells, a third sensing operation, a fourth sensing operation, and the like may be performed after the second sensing operation.

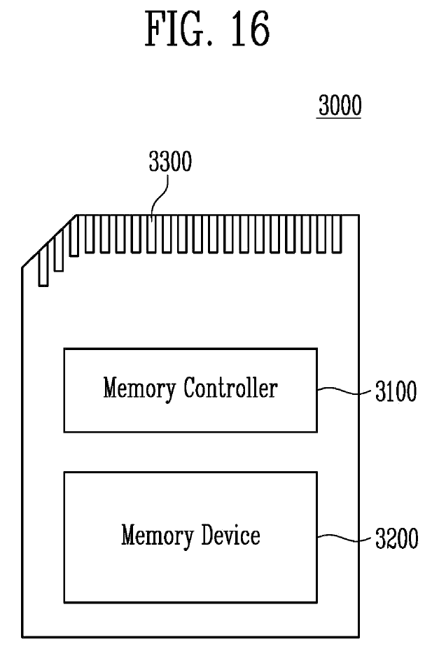

FIG. 16 is a block diagram illustrating a memory card system 3000 according to an embodiment of the present disclosure.

Referring to FIG. 16, the memory card system 3000 may include a memory controller 3100, a memory device 3200, and a connector 3300.

The memory controller 3100 may be coupled to the memory device 3200. The memory controller 3100 may access the memory device 3200. For example, the memory controller 3100 may control program, read, erase, and background operations of the memory device 3200. The memory controller 3100 may provide an interface between the memory device 3200 and a host. The memory controller 3100 may drive firmware that controls the memory device 3200. The memory device 3200 may be configured in the same manner as the memory device 100 as described with reference to FIG. 1.

For example, the memory controller 3100 may include components, such as a Random Access Memory (RAM), a processing unit, a host interface, a memory interface, and an ECC circuit.

The memory controller 3100 may communicate with an external device through the connector 3300. The memory controller 3100 may communicate with an external device, such as a host, based on a communication protocol. For example, the memory controller 3100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) protocols. In an embodiment, the connector 3300 may be configured according to at least one of these various communication protocols.

The memory device 3200 may be implemented with one or more types of nonvolatile memory elements, such as Electrically Erasable and Programmable Read-Only Memory (EEPROM), NAND flash memory, NOR flash memory, Phase-change RAM (PRAM), Resistive RAM (ReRAM), Ferroelectric RAM (FRAM), and Spin Transfer Torque Magnetic RAM (STT-MRAM).

The memory controller 3100 and the memory device 3200 may be integrated into a single semiconductor device to form a memory card. For example, the memory controller 3100 and the memory device 3200 may be integrated into a single semiconductor device to form a memory card, such as a personal computer memory card international association (PCMCIA) card, a compact flash (CF) card, a smart media card (SM, or SMC), a memory stick, a multimedia card (MMC, RS-MMC, MMCmicro, or eMMC), an SD card (SD, miniSD, microSD, or SDHC), a universal flash storage (UFS), and the like.

The memory device 3200 may perform a sensing operation. The sensing operation may be included in a read operation or a verify operation. When the memory device 3200 performs the sensing operation, the memory device 3200 may control voltages applied to a plurality of lines coupled to a memory block. For example, the memory device 3200 may control a voltage applied to a plurality of word lines.

According to an embodiment, the memory device 3200 may determine an equalizing time period during which an equalizing voltage is applied to the plurality of word lines after the sensing operation. For example, the memory device 3200 may determine the equalizing time period based on the magnitude of the sensing voltage applied to the selected word line during the sensing operation. For example, the memory device 3200 may determine different equalizing time periods for each of the sensing operations for a plurality of data bits included in selected memory cells. For example, a first equalizing time period after a first sensing operation for a first data bit may be different from a second equalizing time period after a second sensing operation for a second data bit. For example, the memory device 3200 may include the word line control circuit 131 as described with reference to FIGS. 1 and 2.

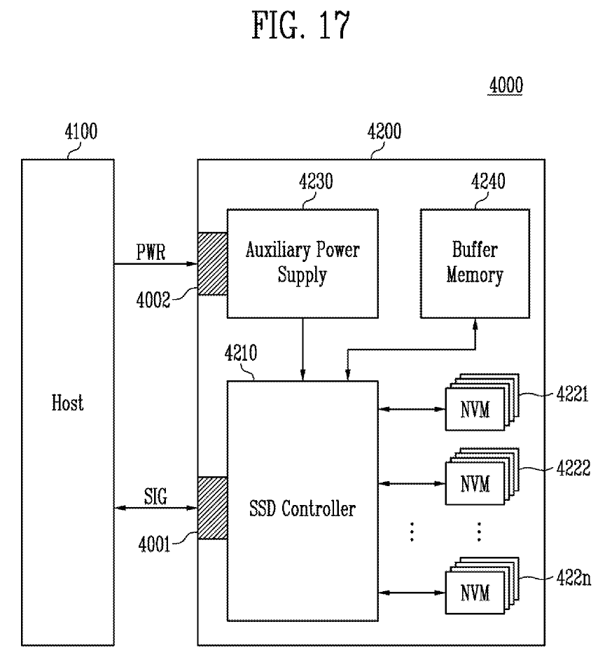

FIG. 17 is a block diagram illustrating a solid state drive (SSD) system 4000 including a storage device according to an embodiment of the present disclosure.

Referring to FIG. 17, the SSD system 4000 may include a host 4100 and an SSD 4200. The SSD 4200 may exchange signals with the host 4100 through a signal connector 4001 and may receive power through a power connector 4002. The SSD 4200 may include an SSD controller 4210, a plurality of flash memories 4221 to 422n, an auxiliary power supply 4230, and a buffer memory 4240.

According to an embodiment, the SSD controller 4210 may function as the memory controller 200 as described with reference to FIG. 1.

The SSD controller 4210 may control the plurality of flash memories 4221 to 422n in response to signals SIG received from the host 4100. In an embodiment, the signals SIG may be based on the interfaces of the host 4100 and the SSD 4200. For example, the signals SIG may be configured according to at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) interfaces.

The auxiliary power supply 4230 may be coupled to the host 4100 through the power connector 4002. The auxiliary power supply 4230 may be supplied and charged with the power from the host 4100. The auxiliary power supply 4230 may supply the power to the SSD 4200 when the power is not smoothly or consistently supplied from the host 4100. In an embodiment, the auxiliary power supply 4230 may be located inside or outside the SSD 4200. For example, the auxiliary power supply 4230 may be disposed on a main board and may supply auxiliary power to the SSD 4200.

The buffer memory 4240 may serve as a buffer memory of the SSD 4200. For example, the buffer memory 4240 may temporarily store data received from the host 4100 or data received from the plurality of flash memories 4221 to 422n, or may temporarily store metadata, such as mapping tables, of the flash memories 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to an embodiment, the SSD 4200 may perform a sensing operation for the plurality of flash memories 4221 to 422n. The sensing operation may be included in a read operation or a verify operation. When the SSD 4200 performs the sensing operation, the SSD 4200 may control the voltage applied to a plurality of lines coupled to a memory block included in the plurality of flash memories 4221 to 422n.

For example, when the sensing operation is started, the SSD 4200 may apply a sensing voltage to a selected word line and a pass voltage to unselected word lines among the plurality of lines coupled to the memory block. The SSD 4200 may control a voltage applied to drain select lines and source select lines among the plurality of lines coupled to the memory block.

For example, when the SSD 4200 applies the sensing voltage to the selected word line, the SSD 4200 may apply a turn-on voltage to the selected drain select line and the selected source select line. The turn-on voltage applied to the selected drain select line and the selected source select line may be maintained for a predetermined time after the sensing operation is terminated and an equalizing operation is started.

According to an embodiment, the SSD 4200 may determine an equalizing time period during which an equalizing voltage is applied to a plurality of word lines after the sensing operation. For example, the SSD 4200 may determine the equalizing time period based on the magnitude of the sensing voltage applied to the selected word line during the sensing operation. For example, the SSD 4200 may determine different equalizing time periods for each of the sensing operations for a plurality of data bits included in the selected memory cells. For example, a first equalizing time period after a first sensing operation for a first data bit may be different from a second equalizing time period after a second sensing operation for a second data bit. For example, the SSD 4200 may include the word line control circuit 131 as described with reference to FIGS. 1 and 2.

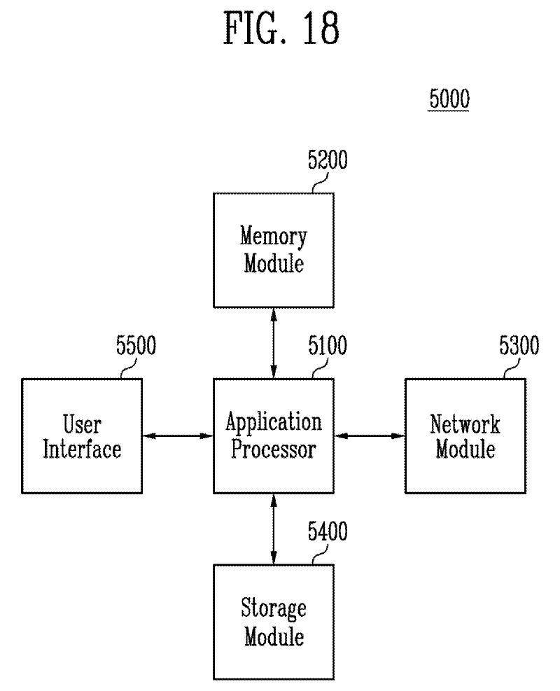

FIG. 18 is a block diagram illustrating a user system 5000 including a storage device according to an embodiment of the present disclosure.

Referring to FIG. 18, the user system 5000 may include an application processor 5100, a memory module 5200, a network module 5300, a storage module 5400, and a user interface 5500.

The application processor 5100 may drive components, an Operating System (OS), or a user program included in the user system 5000. In an embodiment, the application processor 5100 may include controllers, interfaces, graphic engines, and so forth that control the components included in the user system 5000. The application processor 5100 may be a system-on-chip (SoC) processor.

The memory module 5200 may function as a main memory, a working memory, a buffer memory, or a cache memory of the user system 5000. The memory module 5200 may include volatile RAMs such as DRAM, SDRAM, DDR SDRAM, DDR2 SDRAM, DDR3 SDRAM, LPDDR SDARM, LPDDR2 SDRAM, and LPDDR3 SDRAM or nonvolatile RAM such as PRAM, ReRAM, MRAM, and FRAM. In an embodiment, the application processor 5100 and the memory module 5200 may be packaged utilizing package-on-package (POP) technology and in a single semiconductor package.

The network module 5300 may communicate with external devices. For example, the network module 5300 may support wireless communication, such as Code Division Multiple Access (CDMA), Global System for Mobile communication (GSM), wideband CDMA (WCDMA), CDMA-2000, Time Division Multiple Access (TDMA), Long Term Evolution (LTE), Wimax, WLAN, UWB, Bluetooth, and WiFi communication. In an embodiment, the network module 5300 may be included in the application processor 5100.

The storage module 5400 may store data. For example, the storage module 5400 may store data received from the application processor 5100. Alternatively, the storage module 5400 may transfer the data stored in the storage module 5400 to the application processor 5100. In an embodiment, the storage module 5400 may be implemented with a nonvolatile semiconductor memory device, such as a Phase-change RAM (PRAM), a Magnetic RAM (MRAM), a Resistive RAM (RRAM), a NAND flash memory, a NOR flash memory, or a NAND flash memory having a three-dimensional (3D) structure. According to an embodiment, the storage module 5400 may be a removable storage medium or a removable drive, such as a memory card or an external drive of the user system 5000.

For example, the storage module 5400 may include a plurality of non-volatile memory devices, and the plurality of non-volatile memory devices may operate in a similar manner as the memory device 100 described with reference to FIGS. 1 and 2

The user interface 5500 may include interfaces that input data and commands to the application processor 5100 or output data to an external device. In an embodiment, the user interface 5500 may include user input interfaces such as a keyboard, a keypad, a button, a touch panel, a touch screen, a touch pad, a touch ball, a camera, a microphone, a gyroscope sensor, a vibration sensor, and a piezoelectric device. The user interface 5500 may include user output interfaces such as a Liquid Crystal Display (LCD), an Organic Light Emitting Diode (OLED) display device, an Active Matrix OLED (AMOLED) display device, an LED, a speaker, and a monitor.

According to an embodiment, the storage module 5400 performs a sensing operation. The sensing operation may be included in a read operation or a verify operation. When the storage module 5400 performs the sensing operation, the storage module 5400 may control voltages applied to a plurality of lines coupled to a memory block included in the storage module 5400.

For example, when the sensing operation is started, the storage module 5400 may apply a sensing voltage to a selected word line among the plurality of lines coupled to the memory block and a pass voltage to unselected word lines. The storage module 5400 may control a voltage applied to a drain select line and a source select line among the plurality of lines coupled to the memory block.

For example, when the storage module 5400 applies the sensing voltage to the selected word line, the storage module 5400 may apply a turn-on voltage to a selected drain select line and a selected source select line. The turn-on voltage applied to the selected drain select line and the selected source select line may be maintained for a predetermined time after the sensing operation is terminated and an equalizing operation is started.

According to an embodiment, the storage module 5400 may determine an equalizing time period during which an equalizing voltage is applied to a plurality of word lines after the sensing operation. For example, the storage module 5400 may determine the equalizing time period based on the magnitude of the sensing voltage applied to a selected word line during the sensing operation. For example, the storage module 5400 may determine different equalizing time period s for each of the sensing operations for a plurality of data bits included in selected memory cells. For example, a first equalizing time period after a first sensing operation for a first data bit may be different from a second equalizing time period after a second sensing operation for a second data bit. For example, the storage module 5400 may include the word line control circuit 131 as described with reference to FIGS. 1 and 2.

According to an embodiment of the present disclosure, a memory device and an operating method thereof may control a voltage applied to each line to prevent or reduce channel negative boosting during a read operation or a verify operation.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a plurality of memory cells coupled to each of a plurality of word lines;
a peripheral circuit configured to perform a first sensing operation on first memory cells, among the plurality of memory cells, coupled to a selected word line by applying different voltages to the selected word line and unselected word lines among the plurality of word lines; and
control logic configured to control the peripheral circuit to perform an operation including applying voltages to the plurality of word lines;
wherein the control logic determines, based on a magnitude of a first sensing voltage applied to the selected word line during the first sensing operation, a first equalizing time period during which an equalizing voltage is applied to the plurality of word lines after the first sensing operation.

2. The memory device of claim 1, wherein the first sensing voltage comprises at least one of a plurality of voltage levels used to identify a plurality of threshold voltage levels; and
wherein the control logic is configured to determine the first equalizing time period based on a voltage level of a last-applied voltage during the first sensing operation.

3. The memory device of claim 1, wherein each of the first memory cells stores a first data bit and a second data bit;
wherein the control logic is configured to control the peripheral circuit to apply the first sensing voltage to the selected word line during the first sensing operation including sensing the first data bit stored in each of the first memory cells; and
wherein the control logic is configured to control the peripheral circuit to apply a second sensing voltage to the selected word line during a second sensing operation including sensing the second data bit stored in each of the first memory cells.

4. The memory device of claim 3, wherein the control logic is configured to determine, based on a comparison of the first sensing voltage and the second sensing voltage a second equalizing time period during which the equalizing voltage is applied to the plurality of word lines after the second sensing operation.

5. The memory device of claim 3, wherein the first sensing voltage comprises at least one of a plurality of voltage levels used to identify a plurality of threshold voltage levels;
wherein the second sensing voltage comprises at least one other of the plurality of voltage levels; and
wherein the control logic is configured to determine, based on a comparison of a first voltage level that is a level of a last-applied voltage to the selected word line during the first sensing operation and a second voltage level that is a level of a last-applied voltage to the selected word line during the second sensing operation, a second equalizing time period during which the equalizing voltage is applied to the plurality of word lines after the second sensing operation.

6. The memory device of claim 5, wherein the first voltage level is lower than the second voltage level; and
wherein the control logic is configured to determine the second equalizing time period as shorter than the first equalizing time period.

7. The memory device of claim 3, wherein the first sensing voltage comprises at least one of a plurality of voltage levels used to distinguish between a plurality of threshold voltage states;
wherein the second sensing voltage comprises at least one other of the plurality of voltage levels;
wherein the control logic determines a reference voltage value based on the first voltage level that is a level of a last-applied voltage to the selected word line during the first sensing operation; and
wherein the control logic is configured to determine, after the second sensing operation, a time period as a second equalizing time period during which a voltage value of the selected word line reaches the reference voltage value from a second voltage level that is a level of a last-applied voltage to the selected word line during the second sensing operation.

8. The memory device of claim 1, wherein the first sensing voltage comprises at least one of a plurality of voltage levels to identify the plurality of threshold voltage levels;
wherein the control logic is configured to determine a reference voltage value based on a lowest voltage level among the plurality of voltage levels; and
wherein the control logic is configured to determine a time period during which a voltage value of the selected word line reaches the reference voltage value from the first sensing voltage as the first equalizing time period.

9. A method of operating a memory device, the method comprising:
applying a pass voltage to an unselected word line of a plurality of word lines;
applying a first sensing voltage to a selected word line of the plurality of word lines; and
applying an equalizing voltage to the plurality of word lines during a first equalizing time period determined based on the first sensing voltage.

10. The method of claim 9, wherein the applying the first sensing voltage comprises:
applying, to the selected word line, at least one voltage level of a plurality of voltage levels to identify a plurality of threshold voltage levels; and
determining whether a threshold voltage of each memory cell coupled to the selected word line is greater than the at least one voltage level applied to the selected word line.

11. The method of claim 10, wherein the first equalizing time period is determined based on a voltage level of a last-applied voltage while applying of the first sensing voltage.

12. The method of claim 9, further comprising:
discharging the plurality of word lines; and
applying a second sensing voltage to the selected word line of the plurality of word lines.

13. The method of claim 12, further comprising applying the equalizing voltage to the plurality of word lines during a second equalizing time period determined based on a result of comparison of the first sensing voltage and the second sensing voltage.

14. The method of claim 12, wherein the applying the first sensing voltage to the selected word line comprises applying at least one of a plurality of voltage levels used to identify a plurality of threshold voltage levels to the selected word line;
wherein the applying the second sensing voltage to the selected word line comprises applying at least one other of the plurality of voltage levels to the selected word line;
the method further comprising applying the equalizing voltage to the plurality of word lines during a second equalizing time period determined based on a result of comparison of a voltage level of a last-applied voltage while applying the first sensing voltage to the selected word line and a voltage level of a last-applied voltage while applying the second sensing voltage to the selected word line.

15. The method of claim 12, further comprising applying the equalizing voltage to the plurality of word lines during a second equalizing time period determined as a time during which a voltage value of the selected word line reaches a reference voltage value from the second sensing voltage; and
wherein the reference voltage value is reached when the equalizing voltage is applied to the selected word line at the first sensing voltage during the first equalizing time period.

16. A method of operating a memory device, the method comprising:
applying a pass voltage to unselected word lines of a plurality of word lines;
applying a first sensing voltage to a selected word line of the plurality of word lines; and
performing a first equalizing process by applying an equalizing voltage to the plurality of word lines until a voltage value of the selected word line reaches a reference voltage value.

17. The method of claim 16, further comprising:
discharging the plurality of word lines;
applying a second sensing voltage to the selected word line of the plurality of word lines; and
performing a second equalizing process by applying the equalizing voltage to the plurality of word lines until the voltage value of the selected word line reaches the reference voltage value.

18. The method of claim 17, wherein when a voltage level of the first sensing voltage is less than a voltage level of the second sensing voltage, a second equalizing time period during which the equalizing voltage is applied to the plurality of word lines in the first equalizing process is shorter than a first equalizing time period during which the equalizing voltage is applied to the plurality of word lines during the second equalizing process; and
wherein the second equalizing time period is longer than the first equalizing time period when the voltage level of the first sensing voltage is greater than the voltage level of the second sensing voltage.

19. The method of claim 17, wherein the applying the first sensing voltage comprises applying at least one of a plurality of voltage levels used to identify a plurality of threshold voltage states to the selected word line to verify a first data bit stored in a first memory cell coupled to the selected word line; and
wherein the applying the second sensing voltage comprises applying at least one other of the plurality of voltage levels to the selected word line to verify a second data bit stored in the first memory cell.

20. The method of claim 19, wherein the reference voltage value is determined based on a lowest voltage level of the plurality of voltage levels.
